(19) United States
(12) Patent Application Publication
(10) Pub. No.: US 2026/0096460 A1
(43) Pub. Date: Apr. 2, 2026

(54) MOUNTING APPARATUS, MOUNTING METHOD, AND COMPUTER-READABLE RECORDING MEDIUM

(71) Applicant: SHINKAWA LTD., Tokyo (JP)

(72) Inventor: Kohei Seyama, Tokyo (JP)

(73) Assignee: SHINKAWA LTD., Tokyo (JP)

(21) Appl. No.: 19/112,599

(22) PCT Filed: Aug. 18, 2023
(86) PCT No.: PCT/JP2023/029798

§ 371 Date: Mar. 18, 2025

(30) Foreign Application Priority Data
Oct. 18, 2022 (JP) 2022-167109

(51) Int. Cl. H10W 72/00

(52) U.S. Cl. CPC H10W 72/07178; H10W 72/07113; H10W 72/07173

(57) ABSTRACT

Provided is a mounting apparatus including a mounting controller, which adjusts a position of a mounting tool such that a mounted surface of a mounting body is at a same height as an index surface of a calibration index, which is arranged to be imageable by an bottom-up imaging unit and an overhead imaging unit that adopts a Scheimpflug optical system, recognizes a reference position of the mounting body based on a bottom-up image output by causing the bottom-up imaging unit to image the mounting surface, adjusts a position of a stage such that a mounting surface of a planned placement region is at the same height as the index surface, and mounts the mounting surface on the mounted surface based on the recognized reference position.

### TECHNICAL FIELD

The present invention relates to a mounting apparatus, a mounting method, and a mounting control program.

### RELATED ART

In a conventional mounting apparatus, such as a bonding apparatus, first, a camera images a work object, such as a die-pad, from directly above to confirm its position. Then, after retracting the camera, a head that supports the bonding tool is moved directly above the work object to perform the bonding operation. Bonding apparatuses adopting such a configuration not only require operation time but also face problems with accumulation of movement errors relative to the target position for the operation. Thus, the use of an imaging unit adopting a Scheimpflug optical system capable of imaging the work object from an oblique direction has been considered (for example, refer to Patent Document 1).

### CITATION LIST

### Patent Literature

Patent Document 1: Japanese Patent Application Laid-Open Publication No. 2014-179560

### SUMMARY OF INVENTION

### Technical Problem

However, it has been found that imaging units adopting a Scheimpflug optical system, due to the structural characteristics of the optical system, tend to cause minute displacements of optical system elements accompanying temperature changes in the surrounding environment to appear as displacements in the plane direction of the output image. Displacement in the plane direction of the output image causes errors in calculating the target position where the semiconductor chip should be placed, and consequently, hinders the accurate mounting of the semiconductor chip at its original target position. Particularly in so-called stacked die mounting or 2.5-dimensional mounting in which another semiconductor chip is mounted on a semiconductor chip mounted on a substrate in a stacked manner, the height of the placement surface on which each semiconductor chip is placed changes. In such cases, it has also been found there is an issue of different amounts of error for each height.

The present invention is made to solve such problems and provides a mounting apparatus and the like capable of accurately determining the target position for placing each mounting body using an imaging unit adopting a Scheimpflug optical system, even when the temperature of the surrounding environment changes and even in the case where multiple mounting bodies such as semiconductor chips are mounted in a stacked manner, and placing and mounting the mounting body on the target position on a substrate or on another mounting body.

### Solution to Problem

The mounting apparatus according to the first aspect of the present invention includes a mounting tool that picks up and holds a mounting body having a mounting surface, and mounts the mounting surface to a substrate placed on a stage or to a planned placement region set with respect to another mounting body already mounted on the substrate; an overhead imaging unit having an optical system and an imaging element arranged to satisfy a Scheimpflug condition such that a plane parallel to a stage surface of the stage becomes a focal plane, for imaging the planned placement region from above from a same side as the mounting tool with respect to the stage surface; a bottom-up imaging unit for imaging the mounting body held by the mounting tool from below from an opposite side of the overhead imaging unit with respect to the stage surface; a calibration index arranged to be imageable by the overhead imaging unit and the bottom-up imaging unit; and a mounting controller that adjusts a position of the mounting tool such that the mounting surface is at a same height as an index surface of the calibration index, recognizes a reference position of the mounting body based on the bottom-up image output by causing the bottom-up imaging unit to image the mounting surface, adjusts a position of the stage such that a mounted surface of the planned placement region is at the same height as the index surface, and causes mounting to the mounted surface based on the reference position.

Furthermore, the mounting method according to the second aspect of the present invention is a method for mounting a mounting body using a mounting apparatus that includes a mounting tool that picks up and holds a mounting body having a mounting surface, and mounts the mounting surface to a substrate placed on a stage or to a planned placement region set with respect to another mounting body already mounted on the substrate; an overhead imaging unit having an optical system and an imaging element arranged to satisfy a Scheimpflug condition such that a plane parallel to a stage surface of the stage becomes a focal plane, for imaging the planned placement region from above from a same side as the mounting tool with respect to the stage surface; a bottom-up imaging unit for imaging the mounting body held by the mounting tool from below from an opposite side of the overhead imaging unit with respect to the stage surface; and a calibration index arranged to be imageable by the overhead imaging unit and the bottom-up imaging unit. The method includes a mounting control step of adjusting a position of the mounting tool such that the mounting surface is at a same height as an index surface of the calibration index, recognizing a reference position of the mounting body based on the bottom-up image output by causing the bottom-up imaging unit to image the mounting surface, adjusting a position of the stage such that a mounted surface of the planned placement region is at the same height as the index surface, and causing mounting to the mounted surface based on the reference position.

Furthermore, the mounting control program according to the third aspect of the present invention is a mounting control program for controlling a mounting apparatus that includes a mounting tool that picks up and holds a mounting body having a mounting surface, and mounts the mounting surface to a substrate placed on a stage or to a planned placement region set with respect to another mounting body already mounted on the substrate; an overhead imaging unit having an optical system and an imaging element arranged to satisfy a Scheimpflug condition such that a plane parallel to a stage surface of the stage becomes a focal plane, for imaging the planned placement region from above from a same side as the mounting tool with respect to the stage surface, ; a bottom-up imaging unit for imaging the mounting body held by the mounting tool from below from an opposite side of the overhead imaging unit with respect to the stage surface; and a calibration index arranged to be imageable by the overhead imaging unit and the bottom-up imaging unit. The program causes a computer to execute a mounting control step of adjusting a position of the mounting tool such that the mounting surface is at a same height as an index surface of the calibration index, recognizing a reference position of the mounting body based on the bottom-up image output by causing the bottom-up imaging unit to image the mounting surface, adjusting a position of the stage such that a mounted surface of the planned placement region is at the same height as the index surface, and causing mounting to the mounted surface based on the reference position.

### Effects of Invention

According to the present invention, it is possible to provide a mounting apparatus and the like capable of accurately determining a target position for placing each mounting body using an imaging unit adopting a Scheimpflug optical system, even when the temperature of the surrounding environment changes, or even in the case where multiple mounting bodies such as semiconductor chips are mounted in a stacked manner, and placing and mounting the mounting body at the target position on a substrate or on another mounting body.

### BRIEF DESCRIPTION OF DRAWINGS

FIG. 1 is an overall configuration diagram of a flip chip bonder including a bonding apparatus according to the embodiment.

FIG. 2 is a system configuration diagram of the bonding apparatus.

FIG. 3 is an illusionary diagram for describing a Scheimpflug optical system.

FIG. 4 is a diagram showing three imaging units imaging a calibration index.

FIG. 5 is a diagram showing a bonding tool picking up a first semiconductor chip.

FIG. 6 is a diagram showing a third imaging unit imaging a first semiconductor chip while adjusting the height of a first region surface to the height of an index surface.

FIG. 7 is a diagram schematically showing a bottom-up image output by the third imaging unit.

FIG. 8 is a diagram showing a first imaging unit and a second imaging unit imaging a lead frame, which is a planned placement region.

FIG. 9 is a partial perspective diagram of FIG. 8.

FIG. 10 is a diagram showing the procedure for calculating target coordinates on a die-pad on which the first semiconductor chip is to be placed, based on a first overhead image and a second overhead image.

FIG. 11 is a diagram showing a bonding tool placing and bonding the first semiconductor chip at a target position.

FIG. 12 is a diagram showing the bonding tool retracting.

FIG. 13 is a diagram showing the third imaging unit imaging the second semiconductor chip while adjusting the height of the second region surface to the height of the index surface.

FIG. 14 is a diagram schematically showing a bottom-up image output by the third imaging unit.

FIG. 15 is a diagram showing the first imaging unit and the second imaging unit imaging the first semiconductor chip, which is the planned placement region.

FIG. 16 is a diagram showing the procedure for calculating target coordinates of the first semiconductor chip on which the second semiconductor chip is to be placed, based on a first overhead image and a second overhead image.

FIG. 17 is a diagram showing a bonding tool placing and bonding the second semiconductor chip at a target position.

FIG. 18 is a flow chart describing the bonding procedure for semiconductor chips.

FIG. 19 is a sub-flow chart describing the procedure of the calibration control step.

FIG. 20 is a sub-flow chart describing the procedure of the bonding control step.

FIG. 21 is a diagram showing three imaging units imaging a calibration index in another example.

FIG. 22 is a flow chart describing the bonding procedure for semiconductor chips in another example.

FIG. 23 is a flow chart describing an additional procedure related to a further modification example.

### DESCRIPTION OF THE EMBODIMENTS

The present invention will be described through embodiments of the invention, but the invention related to the scope of the patent claims is not limited to the following embodiments. Furthermore, not all the configurations described in the present embodiments are necessarily essential as means for solving the problems. Moreover, in each figure, in the case where multiple structures having the same or similar configurations exist, in order to avoid complexity, reference numerals may be assigned to some parts while omitting the same reference numerals for others.

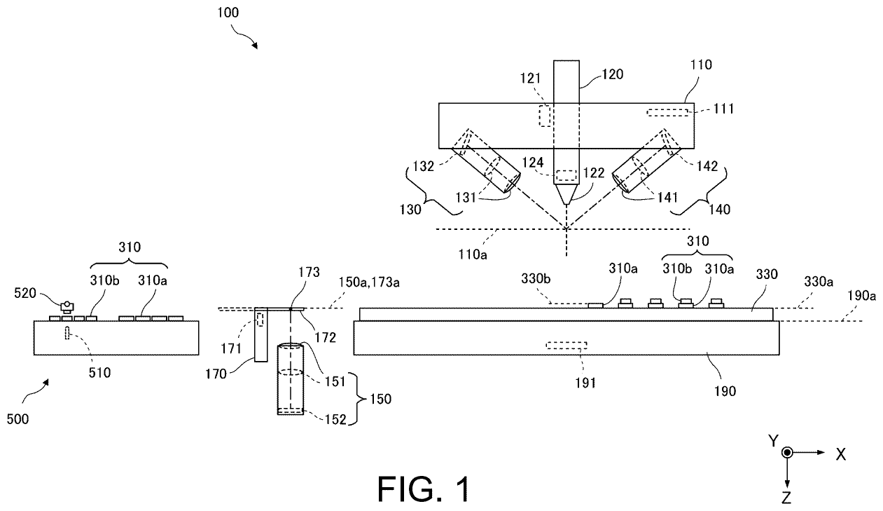

FIG. 1 is an overall configuration diagram of a flip chip bonder including a bonding apparatus 100 as a mounting apparatus according to the embodiment. The flip chip bonder is mainly composed of the bonding apparatus 100 and a chip supply apparatus 500. The chip supply apparatus 500 is an apparatus that places diced semiconductor chips 310 as mounting bodies on its upper surface and supplies them to the bonding apparatus 100. Specifically, the chip supply apparatus 500 includes a pickup mechanism 510 and an inversion mechanism 520. The pickup mechanism 510 is an apparatus that pushes up any placed semiconductor chip 310 towards the inversion mechanism 520. The inversion mechanism 520 is an apparatus that suctions the semiconductor chip 310 pushed up by the pickup mechanism 510 and inverts it, thereby reversing its up-down orientation. In this embodiment, two types of semiconductor chips 310 are prepared: a first semiconductor chip 310a and a second semiconductor chip 310b. The bonding apparatus 100 is an apparatus that picks up the first semiconductor chip 310a or the second semiconductor chip 310b, which has been suctioned in an inverted state by the inversion mechanism 520, using a bonding tool 120 to be described later, and stacks and adheres it to a lead frame 330. In this embodiment, the first semiconductor chip 310a is placed and adhered to the lead frame 330, and the second semiconductor chip 310b is adhered on the first semiconductor chip 310a in a stacked manner. The lead frame 330 is an example of a substrate placed on a stage 190.

The bonding apparatus 100 mainly includes a head 110, a bonding tool 120, a first imaging unit 130, a second imaging unit 140, a third imaging unit 150, a calibration unit 170, and a stage 190. The head 110 supports the bonding tool 120, the first imaging unit 130, and the second imaging unit 140, and may be moved in the plane direction and the vertical direction by a head drive motor 111. In this embodiment, the plane direction is, as shown, a horizontal direction defined by the X-axis direction and the Y-axis direction, and the vertical direction (height direction) is the Z-axis direction perpendicular to the X-axis direction and the Y-axis direction.

The bonding tool 120 may be moved in the height direction relative to the head 110 by a tool drive motor 121, and also may rotate around the Z-axis. The bonding tool 120 is an example of a mounting tool, and has a collet 122 that suctions the semiconductor chip 310 at its tip and a heater 124 that heats the semiconductor chip 310 suctioned onto the collet 122. The bonding tool places the semiconductor chip 310 suctioned onto the collet 122 at a predetermined position, and adheres it by applying pressure with the tip of the collet 122 while heating with the heater 124.

The first imaging unit 130 and the second imaging unit 140 are overhead imaging units that image the lead frame 330 from above. The first imaging unit 130 includes a first optical system 131 and a first imaging element 132, and is obliquely installed on the head 110 with its optical axis directed downward from the bonding tool 120. The first optical system 131 and the first imaging element 132 are arranged to satisfy the Scheimpflug condition such that a plane parallel to a stage surface 190a of the stage 190 becomes a focal plane 110a.

The second imaging unit 140 includes a second optical system 141 and a second imaging element 142, and is obliquely installed on the head 110 on the opposite side of the bonding tool 120 from the first imaging unit 130, with its optical axis directed downward from the bonding tool 120. The second optical system 141 and the second imaging element 142 are arranged to satisfy the Scheimpflug condition such that a plane parallel to the stage surface 190a of the stage 190 becomes the focal plane 110a. In the following description, the first imaging unit 130 and the second imaging unit 140 may be collectively referred to as “overhead imaging units”.

The third imaging unit 150 is a bottom-up imaging unit for imaging the semiconductor chip 310 in a state of being held by the collet 122 of the bonding tool 120, from a bottom-up view. As shown, the third imaging unit 150 is located in the space on the opposite side of the space where the overhead imaging units are located, with the stage surface 190a of the stage 190 as the dividing surface. The third imaging unit 150 includes a third optical system 151 and a third imaging element 152, and is installed with its optical axis directed upward. The third imaging unit 150 is a typical imaging unit with the third optical system 151 and the third imaging element 152 arranged perpendicular to the optical axis, and its focal plane 150a is parallel to the light-receiving surface of the third imaging element 152. Moreover, in the following description, the third imaging unit 150 may be referred to as the “bottom-up imaging unit”.

The calibration unit 170 mainly includes an index drive motor 171, an index plate 172, and a calibration index 173. The calibration index 173 is a reference mark with a defined reference position, such as the intersection point of a cross mark. The index plate 172 is, for example, a thin plate made of glass or transparent resin, with the calibration index 173 printed on one of its surfaces. In other words, the calibration index 173 may be observed from either side of the index plate 172. In this embodiment, the calibration index 173 is printed on the surface of the index plate 172 opposite to the surface facing the third imaging unit 150. In this embodiment, the surface on which the calibration index 173 is printed is referred to as an index surface 173a.

Moreover, if two calibration indices 173 are printed on both sides of the index plate 172 with their reference positions aligned without any XY direction deviation, the index plate 172 does not necessarily need to be transparent. In such a case, the thickness of the index plate 172 is set such that the calibration index 173 facing the third imaging unit 150 falls within the depth of field of the third imaging unit 150. Moreover, the calibration index 173 is not limited to being printed; it may be established by attaching a sticker or by scribing the surface of the index plate 172. In the case where calibration indices 173 are established on both sides of the index plate 172, the surface opposite to the surface facing the third imaging unit 150 may be defined as the index surface 173a. Any Z direction error due to the difference between the calibration index 173 imaged by the first imaging unit 130 and the second imaging unit 140, and the calibration index 173 imaged by the third imaging unit 150 may be corrected based on the thickness of the index plate 172 and the like.

The index drive motor 171 turns the index plate 172 around the Z-axis to move the calibration index 173 near the center of the field of view of the third imaging unit 150 or to retract it from the field of view. When the index plate 172 is turned to put the calibration index 173 into the field of view of the third imaging unit 150, their respective positions are adjusted such that the calibration index 173 becomes the focal plane 150a of the third imaging unit 150. Moreover, since the third optical system 151 takes a certain depth range across the focal plane 150a as the depth of field, a slight deviation between the index surface 173a and the focal plane 150a is tolerated within this depth of field range.

The stage 190 is capable of moving in the plane direction and vertical direction by a stage drive motor 191. Specifically, as will be described later, according to the mounting process, the position of the stage 190 is adjusted such that a first region surface 330a (upper surface of the lead frame 330), which is the region surface of the planned placement region for placing the first semiconductor chip 310a, or a second region surface 330b (upper surface of the first semiconductor chip 310a adhered to the lead frame 330), which is the region surface of the planned placement region for placing the second semiconductor chip 310b, is at the same height as the index surface 173a. Here, a first region surface 220a includes a mounted surface on which a mounting surface of the first semiconductor chip 310a is to be mounted. Moreover, the second region surface 330b includes a mounted surface on which a mounting surface of the second semiconductor chip 310b is to be mounted.

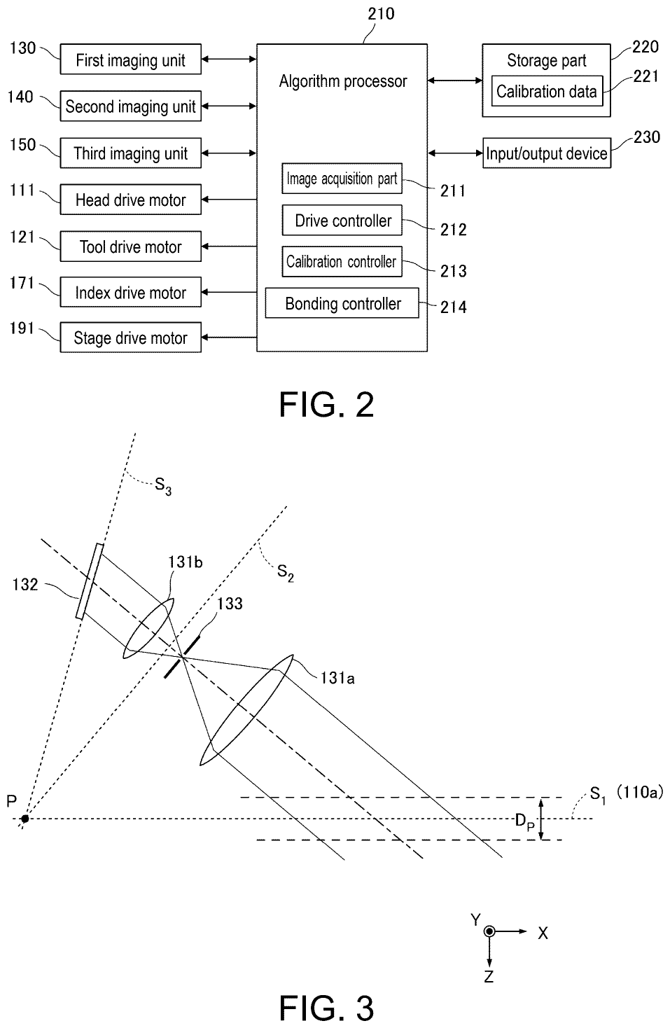

FIG. 2 is a system configuration diagram of the bonding apparatus 100. A control system of the bonding apparatus 100 is mainly composed of an algorithm processor 210, a storage part 220, an input/output device 230, the first imaging unit 130, the second imaging unit 140, the third imaging unit 150, the head drive motor 111, the tool drive motor 121, the index drive motor 171, and the stage drive motor 191.

The algorithm processor 210 is a processor (CPU: Central Processing Unit) that performs control of the bonding apparatus 100 and execution processing of programs. The processor may be configured to work in conjunction with computational processing chips such as ASIC (Application Specific Integrated Circuit) or GPU (Graphics Processing Unit). The algorithm processor 210 reads out the bonding control program stored in the storage part 220 and executes various processes related to bonding control.

The storage part 220 is a non-volatile storage medium, for example, composed of an HDD (Hard Disk Drive). In addition to the bonding control program, the storage part 220 may store various parameter values, functions, lookup tables, etc. used for control and computation. In particular, the storage part 220 stores a calibration data 221. The calibration data 221, as will be described in detail later, is data related to the calibration value for calibrating the difference between a coordinate value calculated based on an overhead image and a coordinate value calculated based on a bottom-up image for the same observation target.

The input/output device 230, for example, includes a keyboard, mouse, and display monitor, and is a device that accepts menu operations by the user and presents information to the user. For instance, the algorithm processor 210 may display the obtained overhead image or bottom-up image on the display monitor, which is one of the input/output devices 230.

The first imaging unit 130 receives an imaging request signal from the algorithm processor 210, executes imaging, and transmits the first overhead image output by the first imaging element 132 as an image signal to the algorithm processor 210. The second imaging unit 140 receives an imaging request signal from the algorithm processor 210, executes imaging, and transmits the second overhead image output by the second imaging element 142 as an image signal to the algorithm processor 210. The third imaging unit 150 receives an imaging request signal from the algorithm processor 210, executes imaging and transmits the bottom-up image output by the third imaging element 152 as an image signal to the algorithm processor 210.

The head drive motor 111 receives a drive signal from the algorithm processor 210 and moves the head 110 in the horizontal direction and height direction. The tool drive motor 121 receives a drive signal from the algorithm processor 210 and moves the bonding tool 120 in the height direction and rotates it around the X-axis. The index drive motor 171 receives a drive signal from the algorithm processor 210 and turns the index plate 172. The stage drive motor 191 receives a drive signal from the algorithm processor 210 and moves the stage 190 in the horizontal direction and height direction.

The algorithm processor 210 also serves as a functional operation part that executes various computations according to the processing instructed by the bonding control program. The algorithm processor 210 may function as an image acquisition part 211, a drive controller 212, a calibration controller 213, and a bonding controller 214. The image acquisition part 211 sends imaging request signals to the first imaging unit 130, the second imaging unit 140, and the third imaging unit 150, and obtains image signals of the first overhead image, the second overhead image, and the bottom-up image. The drive controller 212 sends drive signals corresponding to control amounts to the head drive motor 111, the tool drive motor 121, the index drive motor 171, and the stage drive motor 191, thereby moving the head 110, the bonding tool 120, the index plate 172, and the stage 190 to target positions. Moreover, by sending drive signals to the pickup mechanism 510 and the inversion mechanism 520, the target semiconductor chip 310 is pushed up or suctioned and inverted.

The calibration controller 213 controls the image acquisition part 211 or the drive controller 212, etc., to calculate the calibration value based on the overhead image output by causing the overhead imaging unit to image the calibration index 173, and the bottom-up image output by causing the bottom-up imaging unit to image the calibration index 173. The bonding controller 214 is an example of a mounting controller, and by controlling the image acquisition part 211, the drive controller 212, etc., recognizes the reference position of the semiconductor chip 310 based on a bottom-up image output by causing a bottom-up imaging unit to image the semiconductor chip 310 held in the bonding tool 120. At this time, the bonding controller 214 adjusts the position of the stage 190 such that the region surface of the planned placement region for the semiconductor chip 310 is at the same height as the index surface 173a of the calibration index 173. Then, the bonding tool 120 is caused to place and bond the semiconductor chip 310 in the planned placement region such that the reference position matches the target position determined based on the calibration value and the overhead image output by causing an overhead imaging unit to image the planned placement region where the semiconductor chip 310 is to be placed. At this time, the bonding controller 214 adjusts the position of the head 110 such that the focal plane 110a of the overhead imaging unit is at the same height as the region surface of the planned placement region. The specific control and processing of the calibration controller 213 and the bonding controller 214 will be described in detail later.

FIG. 3 is an illusionary diagram for describing the Scheimpflug optical system adopted in the first imaging unit 130. A similar Scheimpflug optical system is also adopted in the second imaging unit 140, but here, the Scheimpflug optical system of the first imaging unit 130 is described as a representative example.

In FIG. 3, a plane S₁ is the focal plane 110a parallel to the stage surface of the stage 190. A virtual plane S₂ is a plane including a main plane of the first optical system 131 composed of an object-side lens group 131a and an image-side lens group 131b. A plane S₃ is a plane including the light-receiving surface of the first imaging element 132. In this embodiment, the Scheimpflug optical system includes the first optical system 131 and the first imaging element 132 arranged to satisfy the Scheimpflug condition. The arrangement satisfying the Scheimpflug condition is an arrangement where the plane S₁, the virtual plane S₂, and the virtual plane S₃ intersect each other on a common straight line P.

An aperture 133 is placed between the object-side lens group 131a and the image-side lens group 131b to limit the passing light beam. A depth of field D_{P} may be adjusted by the diameter of the aperture 133. Thus, for example, as long as the first region surface 330a or the second region surface 330b is positioned within this depth of field, the first imaging unit 130 may image the pad reference mark or the stack reference mark, which will be described later, in a focused state. In this sense, position control that adjusts the focal plane 110a to be at the same height as a certain surface is allowed to deviate within the range of the depth of field D_{P}.

The second imaging unit 140 includes a similar configuration to the first imaging unit 130 and is arranged on the head 110 symmetrically with respect to the YZ plane including the center axis of the bonding tool 120. Thus, the second imaging unit 140 may also image the pad reference mark or the stack reference mark in a focused state, similar to the first imaging unit 130. It is preferable that the focal plane of the first imaging unit 130 and the focal plane of the second imaging unit 140 coincide at the focal plane 110a. However, even if there is a deviation, as long as parts of their respective depths of field overlap, both may image the pad reference mark or the stack reference mark, etc., in a focused state.

Now, by adopting an imaging unit that employs such a Scheimpflug optical system, it becomes possible to observe directly below the bonding tool 120 from an oblique direction. Thus, even in a state where a semiconductor chip 310 is held by the bonding tool 120 and the bonding tool 120 is moved directly above the planned placement region, it is possible to observe the planned placement region with the overhead imaging unit. In other words, after moving the bonding tool 120 directly above the planned placement region, it is possible to determine the target position for placing the semiconductor chip 310 based on the overhead image output by the overhead imaging unit. As a result, it is sufficient to move the semiconductor chip 310 to the target position from that state, which allows for significantly reducing the movement of the head 110 and the bonding tool 120, thereby achieving a reduction in position deviation associated with movement and shortening the lead time.

However, it has been found that in imaging units adopting a Scheimpflug optical system, due to the arrangement characteristics of the optical system and imaging element, even a slight displacement of the optical system or imaging element accompanying temperature changes in the surrounding environment may cause the output image to be displaced in the plane direction. In other words, it has been found that the image may shift depending on the temperature of the surrounding environment. Such a phenomenon may cause error in the target position when the target position for placing the semiconductor chip 310 is determined based on the overhead image, and results in preventing hinders accurate bonding of the semiconductor chip to its original target position. Especially in cases where a heater 124 for heating the semiconductor chip 310 is installed on the bonding tool 120, the temperature change around the Scheimpflug optical system becomes large. Furthermore, in so-called stacked die mounting or 2.5-dimensional mounting where another semiconductor chip is bonded on a semiconductor chip already bonded to a substrate in a stacked manner, the height of the placement surface on which each semiconductor chip is placed changes. In such cases, the problem that the amount of error varies depending on the height has become apparent.

Thus, in this embodiment, calibration process is executed at a predetermined timing where a temperature change in the surrounding environment is expected, and in the bonding process, by aligning the height of the region surface (first region surface 330a or second region surface 330b) of the planned placement region for the semiconductor chip 310 to be mounted with the height of the index surface 173a of the calibration index 173, the calibration value obtained through the calibration process may be applied to recognize the target position of the semiconductor chip 310 to be stacked on any layer. The calibration process and bonding process are described in order below.

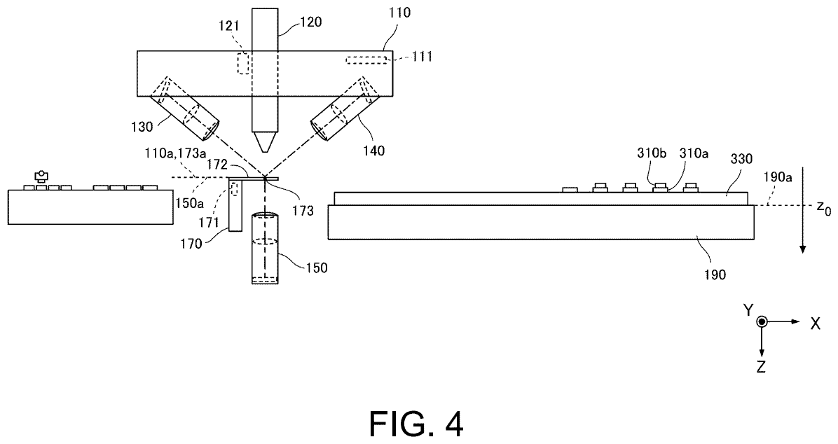

The calibration process is executed by the calibration controller 213. The calibration controller 213 first causes the first imaging unit 130, the second imaging unit 140, and the third imaging unit 150 to image the calibration index 173. FIG. 4 is a diagram showing three imaging units imaging the calibration index 173.

As shown, in starting the calibration process, the calibration controller 213 drives the index drive motor 171 through the drive controller 212 to move the index plate 172 into the field of view of the third imaging unit 150. When the index plate 172 is moved into the field of view of the third imaging unit 150, the calibration index 173 provided on the index plate 172 is positioned approximately at the center of the field of view of the third imaging unit 150, and its index surface 173a becomes the same plane as the focal plane 150a of the third imaging unit 150.

The calibration controller 213 then drives the head drive motor 111 through the drive controller 212 to move the head 110 such that the focal plane 110a of the overhead imaging unit coincides with the index surface 173a, and the calibration index 173 is positioned directly below the bonding tool 120. Moreover, the bonding tool 120 is retracted to a position that does not intrude into the field of view of the overhead imaging unit.

With such state of arrangement, the calibration controller 213 obtains, through the image acquisition part 211, a first overhead image from the first imaging unit 130, a second overhead image from the second imaging unit 140, and a bottom-up image from the third imaging unit 150. Then, from the image coordinates of the calibration index 173 captured in the first overhead image and the second overhead image, the three-dimensional coordinates (Xₕᵣ, Yₕᵣ, Zₕᵣ) of the calibration index 173 are calculated. Moreover, from the image coordinates of the calibration index 173 captured in the bottom-up image, the three-dimensional coordinates (Xₛᵣ, Yₛᵣ, Z sr) of the calibration index 173 are calculated. If the overhead imaging unit is not affected by temperature changes in the surrounding environment, and the coordinates between imaging units are maintained in a correctly adjusted state as in the initial state of the bonding apparatus 100, at least Xₕᵣ should equal Xₛᵣ, and Yₕᵣ should equal Yₛᵣ.

However, as mentioned above, after the bonding apparatus 100 has been in use for some time, the three-dimensional coordinates calculated from the overhead image may include errors due to the influence of temperature changes in the surrounding environment. Thus, this error (ΔX, ΔY) is used as the calibration value. Specifically, the error may be expressed as a difference, where ΔX=Xₛᵣ−Xₕᵣ and ΔY=Yₛᵣ−Yₕᵣ. After calculating the calibration value in this manner, then when the three-dimensional coordinates calculated from an overhead image of an observation target imaged by the overhead imaging unit are (Xₕₜ, Yₕₜ, Zₕₜ), the calibration value may be added to correct the coordinates to (Xₕₜ+ΔX, Yₕₜ+ΔY, Zₕₜ). Assuming the same observation target could be imaged by a bottom-up imaging unit, the corrected coordinate value may be said to have no error compared to the coordinate value calculated from the bottom-up image obtained in this case.

The calibration controller 213 stores the calibration value calculated in this manner as calibration data 221 in the storage part 220. The calibration data 221 is referenced in the bonding process to be described later until it is evaluated that the temperature of the surrounding environment may have changed and recalibration is necessary. In other words, when it is evaluated that recalibration is necessary, the calibration controller 213 repeats the above-described process to update the calibration value.

An example of when recalibration is evaluated as necessary could be the timing when the bonding controller 214 completes bonding of a preset lot of semiconductor chips 310. Specifically, the calibration controller 213 may execute the calibration process in accordance with the timing when a new lot of semiconductor chips 310 is supplied to the chip supply apparatus 500. Moreover, the operation time of the bonding operation executed by the bonding controller 214 may be used as a guide. For example, it may be determined to execute the calibration process when the bonding operation has been continuously executed for 60 minutes. Furthermore, a temperature detector for detecting the temperature of the overhead imaging unit may be provided in the head 110, and the timing may be when the temperature detector detects a preset temperature. Specifically, multiple temperatures may be preset, and the calibration process may be executed when it is detected that the surrounding temperature has fluctuated across these temperatures. By updating the calibration value in this manner, it becomes possible to suppress the error of the coordinate value calculated from the overhead image within a certain range over the period of continuing the bonding process.

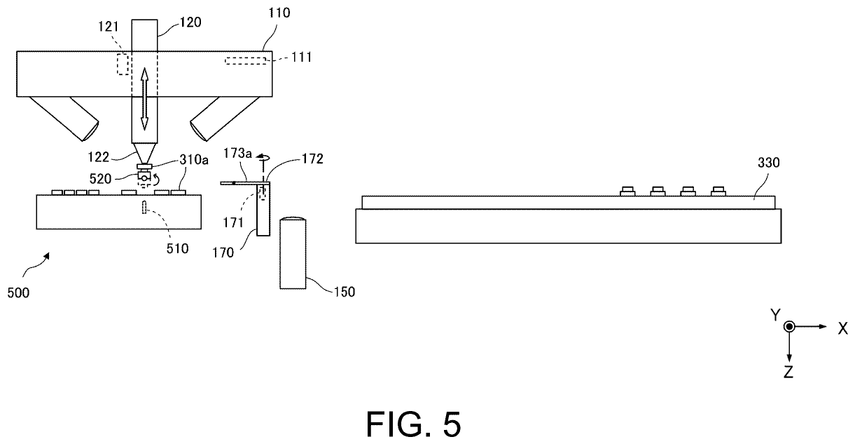

The bonding process is executed by the bonding controller 214. The bonding controller 214 first picks up the target semiconductor chip 310. FIG. 5 is a diagram showing the bonding tool 120 picking up the first semiconductor chip 310a.

The bonding controller 214 moves the head 110 to the upper part of the chip supply apparatus 500 by driving the head drive motor 111 through the drive controller 212, and lowers the bonding tool 120 by driving the tool drive motor 121. In parallel with this, the pickup mechanism 510 pushes up one first semiconductor chip 310 as a bonding target, of the semiconductor chips 310 placed on the chip supply apparatus 500, towards the inversion mechanism 520, and the inversion mechanism 520 suctions and inverts the first semiconductor chip 310a. Then, the lowered bonding tool 120 suctions and picks up the first semiconductor chip 310a with the collet 122, and raises the bonding tool 120.

In the case where the index plate 172 is positioned within the field of view of the third imaging unit 150, the bonding controller 214 retracts the index plate 172 from the field of view of the third imaging unit 150 before or after the operation of the bonding tool 120 picking up the first semiconductor chip 310a. Specifically, the bonding controller 214 moves the index plate 172 by driving the index drive motor 171 through the drive controller 212.

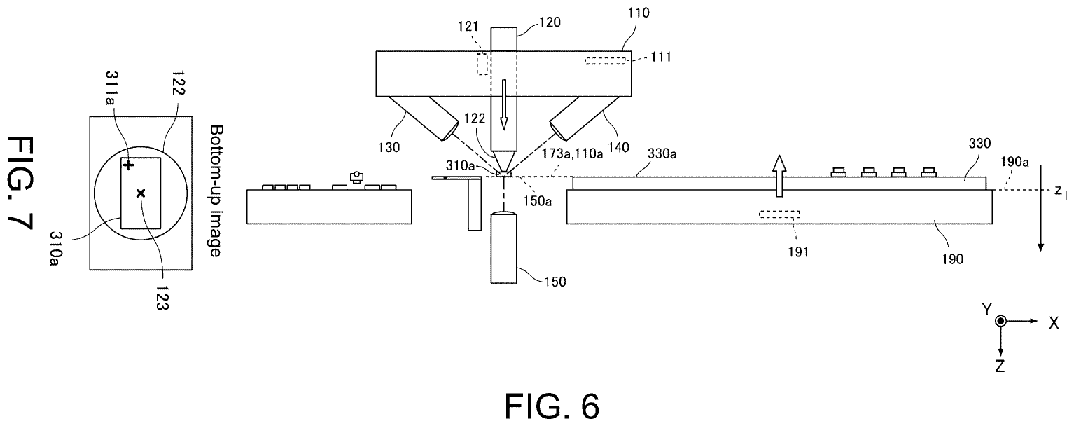

The bonding controller 214 then causes the third imaging unit 150 to image the first semiconductor chip 310a suctioned by the bonding tool 120. FIG. 6 is a diagram showing the third imaging unit 150 imaging the first semiconductor chip 310a suctioned by the bonding tool 120, while adjusting the height of the first region surface 330a, which is the region surface of the planned placement region for placing the first semiconductor chip 310a, to the height of the index surface 173a.

The bonding controller 214 moves the head 110 by driving the head drive motor 111 through the drive controller 212 such that the focal plane 110a of the overhead imaging unit is at the same height as the index surface 173a, and the third imaging unit 150 is positioned directly below the bonding tool 120. Then, by driving the tool drive motor 121, the bonding tool 120 is lowered such that, of the first semiconductor chip 310a being held, a planned contact surface of the lead frame 330 in contact with the planned placement region is at the same height as the index surface 173a. Moreover, the planned contact surface includes the mounting surface of the first semiconductor chip 310a. After such adjustment of the arrangement is completed, the bonding controller 214 causes the third imaging unit 150 to image the planned contact surface of the first semiconductor chip 310a held by the bonding tool 120 through the image acquisition part 211. Moreover, the planned contact surface of the first semiconductor chip 310a is the surface on the opposite side of the surface suctioned on the collet 122, and is the surface facing the third imaging unit 150.

The bonding controller 214 adjusts the position of the stage 190 by driving the stage drive motor 191 through the drive controller 212 before or after the process of causing the third imaging unit 150 to image the planned contact surface of the first semiconductor chip 310a. Specifically, the first region surface 330a, which is the region surface of the planned placement region for the first semiconductor chip 310a, is adjusted to at the same height as the index surface 173a. For example, since the thickness of the lead frame 330 is known, it is sufficient for the bonding controller 214 to cause the stage surface 190a to move to Z=Z₁, which is obtained by subtracting the thickness of the lead frame 330 from the height of the index surface 173a.

Moreover, in the case where the first region surface 330a has already been adjusted to the same height as the index surface 173a, the bonding controller 214 skips the position adjustment of the stage 190. Moreover, the position adjustment of the stage 190 may be executed before the bonding controller 214 starts the operation of placing the first semiconductor chip 310a in the planned placement region.

FIG. 7 is a diagram schematically showing a bottom-up image output by the third imaging unit 150 imaging the first semiconductor chip 310a held by the bonding tool 120. In the drawing, each subject image is described with the reference number of the corresponding subject.

As described above, the bonding tool 120 picks up and holds the semiconductor chip 310 (the first semiconductor chip 310a, the second semiconductor chip 310b) prepared by the chip supply apparatus 500 by suction through the collet 122. At this time, the bonding tool 120 attempts to suction the center of the semiconductor chip 310 in a preset orientation, but in practice, there may be cases deviation occurs in suction. Thus, the bonding controller 214 confirms the actual position and orientation in which the semiconductor chip 310 is held, and recognizes the reference position for placing the semiconductor chip 310 on the lead frame 330.

The bottom-up image shown in FIG. 7 is an image imaged by the third imaging unit 150 looking up at the first semiconductor chip 310a, so the collet 122 holding the first semiconductor chip 310a is also captured in the image. Thus, the bonding controller 214 detects the circle as the outline of the collet 122, and calculates the image coordinates of a collet center 123.

Moreover, in this embodiment, the first semiconductor chip 310a is provided with a chip reference mark 311a on the planned contact surface to be in contact with the lead frame 330, and the bonding controller 214 calculates the image coordinates of the chip reference mark 311a that is captured in the bottom-up image. From the image coordinates of the collet center 123 and the image coordinates of the chip reference mark 311a calculated in this manner, the bonding controller 214 may recognize the actual position and orientation in which the first semiconductor chip 310a is held relative to the collet 122. For example, if the position where the chip reference mark 311a is provided is the reference position for placing the first semiconductor chip 310a on the planned placement region of the lead frame 330, the bonding controller 214 may calculate the three-dimensional coordinates of the reference position of the first semiconductor chip 310a at the time when the bottom-up image was imaged. Thus, even if the bonding tool 120 or the head 110 is subsequently moved, as long as the collet 122 continues to hold the first semiconductor chip 310a, the three-dimensional coordinates of the reference position may be tracked.

After the three-dimensional coordinates of the reference position are recognized, the bonding controller 214 drives the tool drive motor 121 to raise the bonding tool 120 to a position where the first semiconductor chip 310a being held retracts from the field of view of the overhead imaging unit. Then, by driving the head drive motor 111, the head 110 is moved such that the bonding tool 120 is directly above the die-pad, which is the planned placement region for the first semiconductor chip 310a, and such that the focal plane 110a of the overhead imaging unit coincide with the first region surface 330a. Moreover, the raising of the bonding tool 120 and the movement of the head 110 may be performed in parallel if desired.

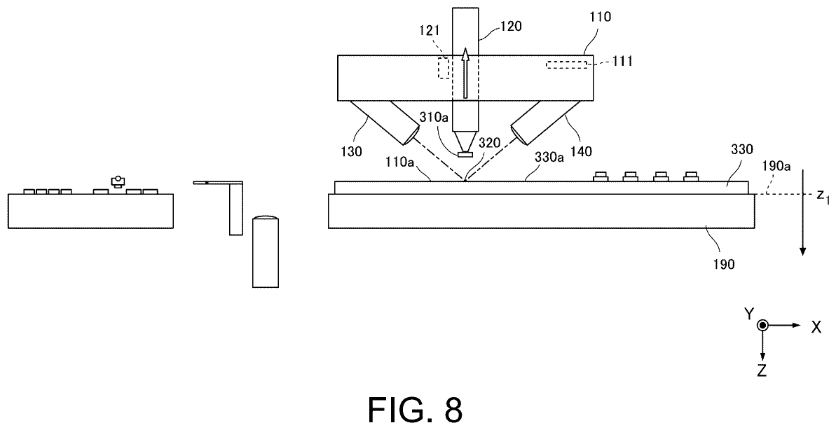

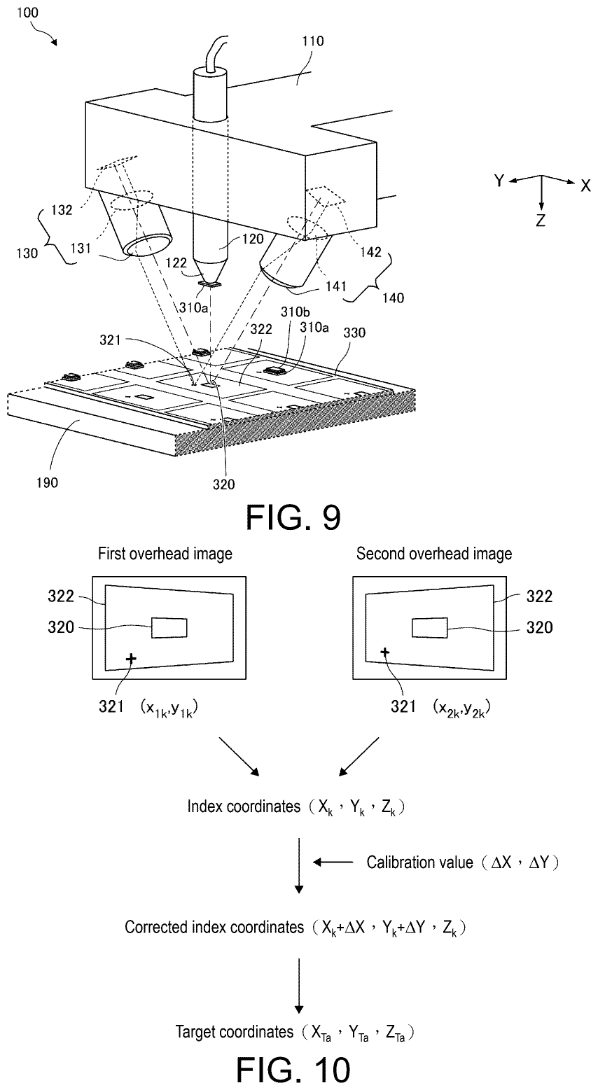

FIG. 8 is a diagram showing the first imaging unit 130 and the second imaging unit 140 imaging the planned placement region on the lead frame 330 when the head 110 and the bonding tool 120 are arranged as described. FIG. 9 is a partial perspective diagram of FIG. 8. In this embodiment, the lead frame 330 has one die-pad 320 in each of the unit regions 322 that will be cut out and enclosed in a single package in the future. The die-pad 320 shown is the planned placement region where the first semiconductor chip 310a will be placed. Moreover, each unit region 322 is provided with a pad reference mark 321 indicating its reference position.

In the state arranged as shown in FIG. 8 and FIG. 9, the first imaging unit 130 and the second imaging unit 140 may each capture the die-pad 320 and the pad reference mark 321 included in the same unit region 322 within their field of view and image them in a focused state. The bonding controller 214 uses the first overhead image output by the first imaging unit 130 and the second overhead image output by the second imaging unit 140 to calculate the coordinates of the target position to which the reference position should be matched when the first semiconductor chip 310a is placed on the die-pad 320.

FIG. 10 is a diagram showing the procedure for calculating the target coordinates for placing the first semiconductor chip 310a, based on the first overhead image and the second overhead image. The first imaging unit 130 images the die-pad 320 from the pad reference mark 321 side, so in its output image, which is the first overhead image, the unit region 322 is captured in a trapezoidal shape that expands towards the pad reference mark 321 side. Conversely, the second imaging unit 140 images the die-pad 320 from the opposite side of the pad reference mark 321, so in its output image, which is the second overhead image, the unit region 322 is captured in a trapezoidal shape that narrows towards the pad reference mark 321 side.

The bonding controller 214 determines image coordinates (x₁ₖ, y₁ₖ) of the pad reference mark 321 from the first overhead image, and also determines image coordinates (x₂ₖ, y₂ₖ) of the pad reference mark 321 from the second overhead image. Then, for example, by referring to a conversion table that converts image coordinates to three-dimensional coordinates, index coordinates (Xₖ, Yₖ, Zₖ), which are the three-dimensional coordinates of the pad reference mark 321, are calculated from these image coordinates. The coordinate values of these index coordinates are provisional target positions for calculating the precise target position, and as mentioned above, they include errors due to the influence of temperature changes in the surrounding environment. Thus, the calibration value (ΔX, ΔY) is read from the calibration data 221 for correction. The coordinate values of the corrected index coordinates (Xₖ+ΔX, Yₖ+ΔY, Zₖ) obtained in this manner may be expected to have no errors with respect to the spatial coordinates calculated from the bottom-up image.

Since the relative position between the preset target position of the die-pad 320 and the pad reference mark 321 is known, the bonding controller 214 may accurately calculate the coordinates (X_{Ta}, Y_{Ta}, Z_{Ta}) of the target position from the corrected index coordinates (Xₖ+ΔX, Yₖ+ΔY, Zₖ).

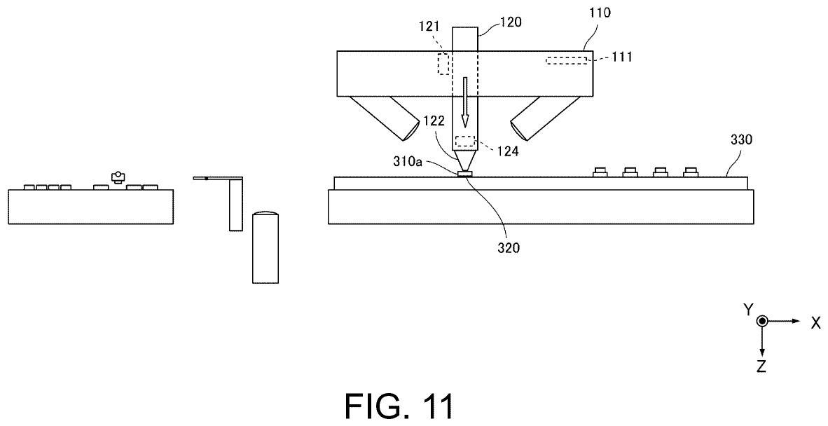

After the coordinates of the target position are determined, the first semiconductor chip 310a is placed and bonded at that target position. FIG. 11 is a diagram showing the bonding tool 120 placing and bonding the first semiconductor chip 310a at the target position.

The bonding controller 214, as described above, tracks and grasps the three-dimensional coordinates of the reference position of the first semiconductor chip 310a with respect to the movement of the bonding tool 120 and the head 110, and moves the first semiconductor chip 310a such that this reference position matches the target position of the die-pad 320. Specifically, through the drive controller 212, the head drive motor 111 is driven to finely adjust the XY direction position of the head 110, and the tool drive motor 121 is driven to finely adjust the rotation amount around the Z-axis of the bonding tool 120. Then, in a state where the X and Y coordinates of the reference position and the X and Y coordinates of the target position respectively coincide, the bonding tool 120 is lowered to place the first semiconductor chip 310a on the die-pad 320. After that, the first semiconductor chip 310a is pressed with the tip of the collet 122 and heated with the heater 124, and is adhere to the die-pad 320.

In this embodiment, as described above, the Z direction position of the head 110 when calculating the calibration value is the same as the Z direction position of the head 110 when the overhead imaging unit images the chip reference mark 311a. Also, as described using FIG. 6 and FIG. 7, the three-dimensional coordinates of the chip reference mark 311a are calculated by aligning the planned contact surface of the first semiconductor chip 310a held by the collet 122 in height with the index surface 173a on which the calibration process was executed. Then, the first region surface 330a is made to coincide in height with the index surface 173a on which the calibration process was executed. In other words, the Z direction position of the head 110 is the same in each case: when obtaining the calibration value, when calculating the three-dimensional coordinates of the chip reference mark 311a, and when placing the first semiconductor chip 310a on the die-pad 320.

Thus, it is not necessary to consider the error in the XY direction between the actual three-dimensional coordinates and the recognized three-dimensional coordinates that may occur when moving the head 110 or the bonding tool 120 in the Z direction. For example, in the state shown in FIG. 8, the bonding tool 120 holds the first semiconductor chip 310a and is retracted from the field of view of the overhead imaging unit, but there may be cases where the actual X and Y coordinates of the reference position in this state do not coincide with the X and Y coordinates recognized by the bonding controller 214 due to the influence of clearances between elements of the movement mechanism that moves the bonding tool 120 up and down. However, as shown in FIG. 11, when placing the first semiconductor chip 310a on the first region surface 330a, the height of the bonding tool 120 becomes the same as the height of the bonding tool 120 when calculating the three-dimensional coordinates of the chip reference mark 311a, and the error factor caused by the movement mechanism is eliminated. In other words, the actual X and Y coordinates of the reference position when placing the first semiconductor chip 310a on the first region surface 330a will coincide with the X and Y coordinates recognized by the bonding controller 214. Thus, in this embodiment, in the case where the first semiconductor chip 310a is placed and adhered on the die-pad 320, the height of the first region surface 330a coincides with the height of the index surface 173a.

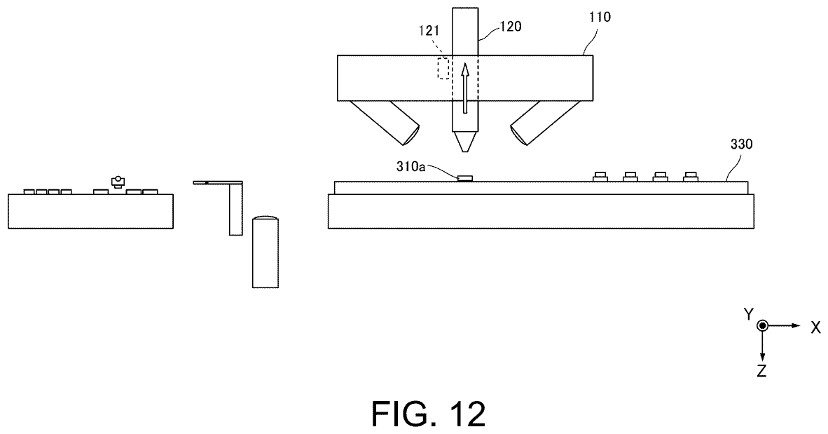

FIG. 12 is a diagram showing the bonding tool 120 retracting. As shown, after the bonding of the first semiconductor chip 310a is completed, the bonding controller 214 raises the bonding tool 120 by driving the tool drive motor 121 through the drive controller 212.

The bonding controller 214 then initiates the process of bonding and stacking the second semiconductor chip 310b on the first semiconductor chip 310a, which has completed bonding. Similar to the pickup of the first semiconductor chip 310a described with reference to FIG. 5, the bonding controller 214, of the semiconductor chips 310 placed on the chip supply apparatus 500 using the pickup mechanism 510 and the inversion mechanism 520, inverts one second semiconductor chip 310b as the bonding target, and picks it up by suction through the collet 122.

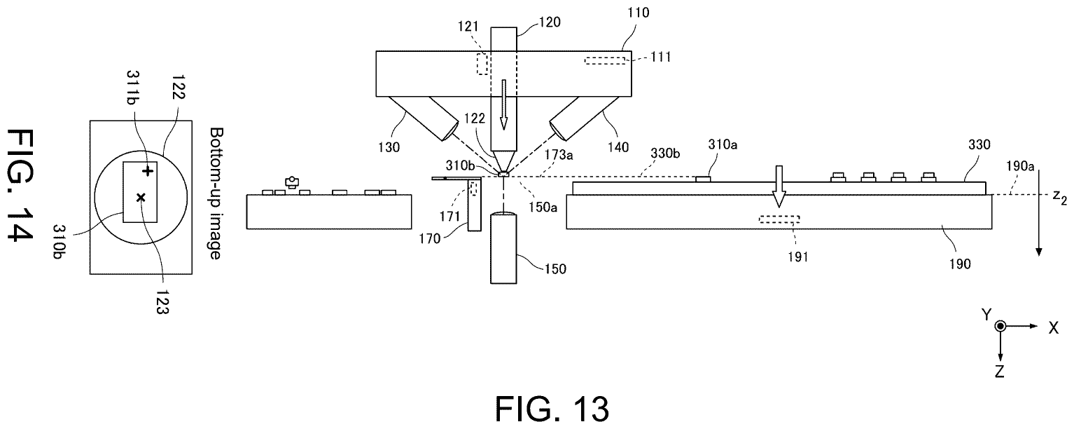

FIG. 13 is a diagram showing the third imaging unit 150 imaging the second semiconductor chip 310b suctioned by the bonding tool 120, while adjusting the height of the second region surface 330b, which is the region surface of the planned placement region for placing the second semiconductor chip 310b, to the height of the index surface 173a.

The bonding controller 214 moves the head 110 by driving the head drive motor 111 through the drive controller 212 such that the focal plane 110a of the overhead imaging unit is at the same height as the index surface 173a, and the third imaging unit 150 is positioned directly below the bonding tool 120. Then, the tool drive motor 121 is driven to lower the bonding tool 120 such that, of the second semiconductor chips 310b being held, the planned contact surface to be in contact with the planned placement region of the first semiconductor chip 310a, which is a stacking object, is at the same height as the index surface 173a. Moreover, the planned contact surface includes the mounting surface of the second semiconductor chip 310b. After such adjustment of the arrangement is completed, the bonding controller 214 causes the third imaging unit 150 to image the planned contact surface of the second semiconductor chip 310b held by the bonding tool 120 through the image acquisition part 211. Moreover, the planned contact surface of the second semiconductor chip 310b is the surface opposite to the surface suctioned by the collet 122, and is the surface facing the third imaging unit 150.

The bonding controller 214, before or after the process of causing the third imaging unit 150 to image the planned contact surface of the second semiconductor chip 310b, adjusts the position of the stage 190 by driving the stage drive motor 191 through the drive controller 212. Specifically, the second region surface 330b, which is the region surface of the planned placement region for the second semiconductor chip 310b, is adjusted to be at the same height as the index surface 173a. For example, since the thicknesses of the lead frame 330 and the first semiconductor chip 310a are known, it is sufficient that the bonding controller 214 moves the stage surface 190a to Z=Z₂, which is obtained by subtracting the thickness of the lead frame 330 and the thickness of the first semiconductor chip 310a from the height of the index surface 173a.

Moreover, if the second region surface 330b has already been adjusted to the same height as the index surface 173a, the bonding controller 214 skips the position adjustment of the stage 190. Moreover, the position adjustment of the stage 190 may be executed at any time before the bonding controller 214 starts the operation of placing the second semiconductor chip 310b on the planned placement region.

FIG. 14 is a schematic diagram showing a bottom-up image output by the third imaging unit 150 imaging the second semiconductor chip 310b held by the bonding tool 120. The bonding controller 214, similar to the case of the first semiconductor chip 310a, confirms the suction position and orientation of the second semiconductor chip 310b with respect to the collet 122, and recognizes the reference position for placing the second semiconductor chip 310b onto the first semiconductor chip 310a.

The bonding controller 214 detects the circle as the outline of the collet 122, and calculates the image coordinates of the collet center 123. Moreover, in this embodiment, the second semiconductor chip 310b has a chip reference mark 311b provided on the planned contact surface to be in contact with the first semiconductor chip 310a, and the bonding controller 214 calculates the image coordinates of the chip reference mark 311b captured in the bottom-up image. From the image coordinates of the collet center 123 and the image coordinates of chip reference mark 311b calculated in this manner, the bonding controller 214 may recognize the actual position and orientation in which the second semiconductor chip 310b is held relative to the collet 122. Thus, even if the bonding tool 120 or the head 110 is subsequently moved, as long as the collet 122 continues to hold the second semiconductor chip 310b, the three-dimensional coordinates of the reference position may be tracked.

After the three-dimensional coordinates of the reference position are recognized, the bonding controller 214 drives the tool drive motor 121 to raise the bonding tool 120 to a position where the second semiconductor chip 310b being held retracts from the field of view of the overhead imaging unit. Then, by driving the head drive motor 111, the head 110 is moved such that the bonding tool 120 is directly above the first semiconductor chip 310a, which is the planned placement region for the second semiconductor chip 310b, and such that the focal plane 110a of the overhead imaging unit coincides with the second region surface 330b. Moreover, the raising of the bonding tool 120 and the movement of the head 110 may be performed in parallel.

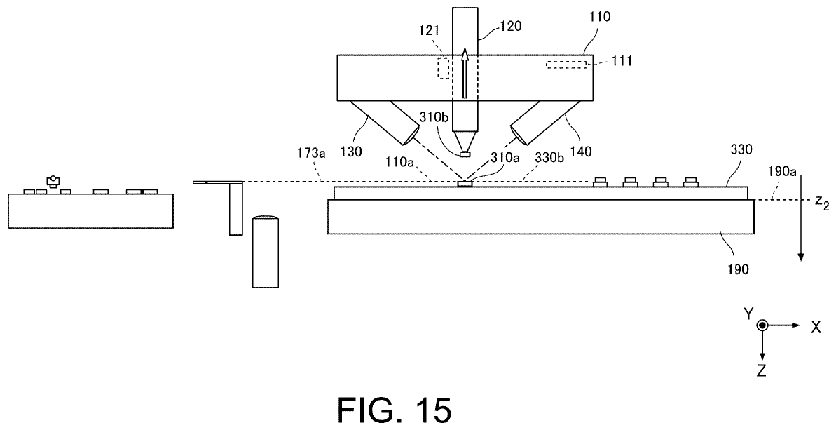

FIG. 15 is a diagram showing the first imaging unit 130 and the second imaging unit 140 imaging the planned placement region on the first semiconductor chip 310a with the head 110 and the bonding tool 120 arranged as described. In this state, the first imaging unit 130 and the second imaging unit 140 may each capture the target planned placement region on the first semiconductor chip 310a within their field of view and image it in a focused state. The bonding controller 214 uses the first overhead image output by the first imaging unit 130 and the second overhead image output by the second imaging unit 140 to calculate the coordinates of the target position where the reference position should be matched when the second semiconductor chip 310b is placed onto the first semiconductor chip 310a.

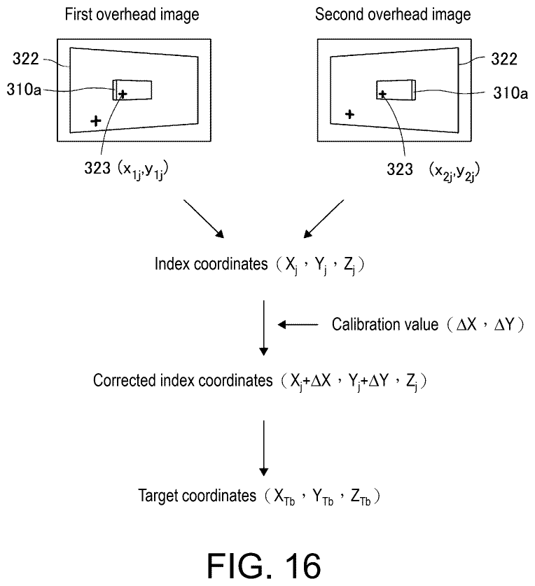

FIG. 16 is a diagram showing the procedure for calculating the target coordinates for placing the second semiconductor chip 310b, based on first overhead image and the second overhead image. As shown, the first semiconductor chip 310a to be stacked is already bonded within the unit region 322 on the lead frame 330, and in both the first overhead image and the second overhead image, a stack reference mark 323 indicating the reference position on the upper surface of the first semiconductor chip 310a is captured.

The bonding controller 214 determines image coordinates (x₁ⱼ, y₁ⱼ) of the stack reference mark 323 from the first overhead image, and also determines the image coordinates (x₂ⱼ, y₂ⱼ) of the stack reference mark 323 from the second overhead image. Then, it calculates index coordinates (Xⱼ, Yⱼ, Zⱼ), which are three-dimensional coordinates of the pad reference mark 321, from the image coordinates. The coordinate values of the index coordinates are provisional target positions for calculating the precise target position, and as mentioned above, they contain errors due to the influence of temperature changes in the surrounding environment. Thus, the calibration value (ΔX, ΔY) is read from the calibration data 221 for correction. The coordinate values of the corrected index coordinates (Xⱼ+ΔX, Yⱼ+ΔY, Zⱼ) obtained in this manner may be expected to have no errors with respect to the spatial coordinates calculated from the bottom-up image. Since the relative position between the preset target position on the first semiconductor chip 310a and the stack reference mark 323 is known, the bonding controller 214 may accurately calculate the coordinates (X_{Tb}, Y_{Tb}, Z_{Tb}) of the target position from the corrected index coordinates (Xⱼ+ΔX, Yⱼ+ΔY, Zⱼ).

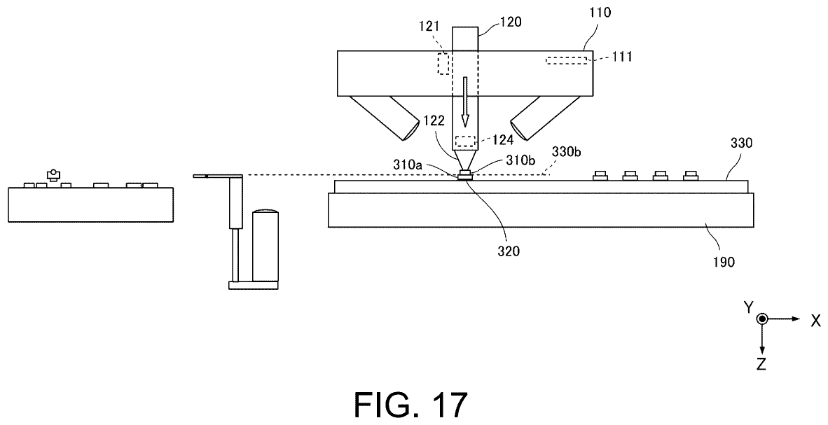

After the coordinates of the target position are determined, the second semiconductor chip 310b is placed and bonded at that target position. FIG. 17 is a diagram showing the bonding tool 120 placing and bonding the second semiconductor chip 310b at the target position on the first semiconductor chip 310a.

The bonding controller 214, as described above, tracks and grasps the three-dimensional coordinates of the reference position of the second semiconductor chip 310b with respect to the movement of the bonding tool 120 and the head 110, and moves the second semiconductor chip 310b such that this reference position matches the target position on the first semiconductor chip 310a. Specifically, through the drive controller 212, the head drive motor 111 is driven to finely adjust the XY direction position of the head 110, and the tool drive motor 121 is driven to finely adjust the rotation amount around the Z-axis of the bonding tool 120. Then, in a state where the X and Y coordinates of the reference position and the X and Y coordinates of the target position respectively coincide, the bonding tool 120 is lowered to place the second semiconductor chip 310b on the first semiconductor chip 310a. After that, the second semiconductor chip 310b is pressed with the tip of the collet 122 and heated with the heater 124, and is adhered to the first semiconductor chip 310a.

In this embodiment, as described above, the Z direction position of the head 110 when calculating the calibration value is the same as the Z direction position of the head 110 when the overhead imaging unit images the chip reference mark 311b. Moreover, as described using FIG. 13 and FIG. 14, the three-dimensional coordinates of the chip reference mark 311b are calculated by aligning the planned contact surface of the second semiconductor chip 310b held by the collet 122 in height with the index surface 173a on which the calibration process was executed. Then, the second region surface 330b is made to coincide in height with the index surface 173a on which the calibration process was executed. In other words, the Z direction position of the head 110 is the same in each case: when obtaining the calibration value, when calculating the three-dimensional coordinates of the chip reference mark 311b, and when placing the second semiconductor chip 310b on the first semiconductor chip 310a.

Thus, it is not necessary to consider the error in the XY direction between the actual three-dimensional coordinates and the recognized three-dimensional coordinates that may occur when moving the head 110 or the bonding tool 120 in the Z direction. For example, in the state shown in FIG. 15, the bonding tool 120 holds the second semiconductor chip 310b and is retracted from the field of view of the overhead imaging unit, but there may be cases where the actual x and y coordinates of the reference position in this state do not coincide with the x and y coordinates recognized by the bonding controller 214 due to the influence of clearances between elements of the movement mechanism that moves the bonding tool 120 up and down. However, as shown in FIG. 17, when placing the second semiconductor chip 310b on the second region surface 330b, the height of the bonding tool 120 becomes the same as the height of the bonding tool 120 when calculating the three-dimensional coordinates of the chip reference mark 311b, and the error factor due to the movement mechanism is eliminated. In other words, the actual x and y coordinates of the reference position when placing the second semiconductor chip 310b on the second region surface 330b will coincide with the x and y coordinates recognized by the bonding controller 214. Thus, in this embodiment, in the case where the second semiconductor chip 310b is placed and adhered to the first semiconductor chip 310a, the height of the second region surface 330b coincides with the height of the index surface 173a.

After the bonding of the second semiconductor chip 310b is completed, the bonding controller 214 raises the bonding tool 120 by driving the tool drive motor 121 through the drive controller 212. In the case of bonding a new semiconductor chip 310, the process is repeated by returning to the state shown in FIG. 5 again. In this embodiment, a step is adopted in which, after bonding the first semiconductor chip 310a to the die-pad 320, the position of the stage 190 is adjusted, and the second semiconductor chip 310b is stacked on the first semiconductor chip 310a, but the processing step is not limited thereto. For example, the first semiconductor chip 310a may be continuously mounted on each of multiple die-pads 320 provided on the lead frame 330, and then the position of the stage 190 may be adjusted to sequentially mount the second semiconductor chip 310b on each of these first semiconductor chips 310a. By adopting such a step, the number of times the position adjustment of the stage 190 is executed can be reduced, which is expected to shorten the lead time.

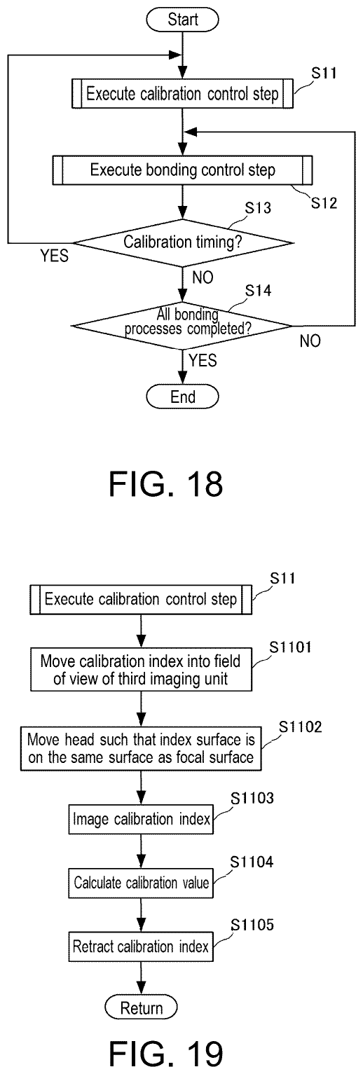

Next, the overall bonding procedure including the calibration process and bonding process described above is summarized along with a flow chart. FIG. 18 is a flow chart describing the bonding procedure of the semiconductor chip 310.

In step S11, the calibration controller 213 starts the calibration control step to perform the calibration process. This will be described in detail later as a sub-flow. Moreover, in the case of starting the bonding process from an initial state where the coordinates between imaging units are correctly adjusted, the first calibration control step may be skipped.

After the calibration controller 213 completes the execution of the calibration control step, the process proceeds to step S12, where the bonding controller 214 starts the bonding control step to perform the bonding process. This will be described in detail later as a sub-flow.

After the bonding controller 214 completes the execution of the bonding control step, the process proceeds to step S13, where the calibration controller 213 determines whether the state of the bonding apparatus 100 at that point satisfies the conditions of the calibration timing preset. The conditions of the preset calibration timing are set as conditions that may be considered to require recalibration. For example, as mentioned above, candidates for the set conditions include the number of completed lots, the operation time of the bonding operation, and the temperature detected by the temperature detector.

In step S13, in the case where the calibration controller 213 determines that the conditions are satisfied, the process returns to step S11. In the case where it is determined that the conditions are not satisfied, the process proceeds to step S14. In the case of proceeding to step S14, the bonding controller 214 determines whether all planned bonding processes have been completed. In the case where it is determined that there are remaining semiconductor chips 310 to be bonded, the process returns to step S12, and in the case where it is determined that all bonding processes have been completed, the series of processes is ended.

FIG. 19 is a sub-flow chart illustrating the procedure of the calibration control step. In the calibration control step, mainly the process described using FIG. 4 is executed. In step S1101, the calibration controller 213 moves the index plate 172 to put the calibration index 173 into the center of the field of view of the third imaging unit 150. Then in step S1102, the calibration controller 213 moves the head 110, such that the index surface 173a of the calibration index 173 is on the same surface as the focal plane 110a of the first imaging unit 130 and the second imaging unit 140, and the calibration index 173 is positioned directly below the bonding tool 120.

The calibration controller 213 proceeds to step S1103 and causes each imaging unit to perform imaging through the image acquisition part 211, obtaining a first overhead image from the first imaging unit 130, a second overhead image from the second imaging unit 140, and a bottom-up image from the third imaging unit 150. Then, in the subsequent step S1104, the three-dimensional coordinates of the calibration index 173 are calculated based on the image coordinates of the image of the calibration index 173 captured in the first overhead image and the second overhead image respectively, and the three-dimensional coordinates of the calibration index 173 are calculated based on the image of the calibration index 173 captured in the bottom-up image. The calibration controller 213 calculates the difference in the XY plane direction among the three-dimensional coordinates thus calculated as a calibration value. The calculated calibration value is stored in the storage part 220 as calibration data 221.

Subsequently, in step S1105, the calibration controller 213 moves the index plate 172 to retract the calibration index 173 from the field of view of the third imaging unit 150. After the retraction of the calibration index 173 is completed, the process returns to the main flow. Moreover, the retraction of the calibration index 173 may be performed during the subsequent bonding process.

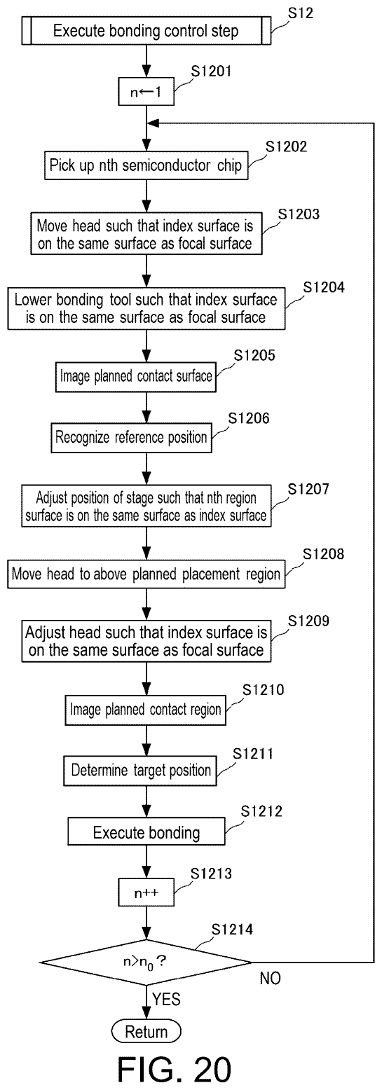

FIG. 20 is a sub-flow chart illustrating the procedure of the bonding control step. In the bonding control step, mainly the process described using FIG. 5 to FIG. 17 is executed. In step S1201, the bonding controller 214 assigns “1” to a counter n.

Proceeding to step S1202, the head 110 is moved to the upper part of the chip supply apparatus 500, and the bonding tool 120 is lowered. Then, of the semiconductor chips 310 placed on the chip supply apparatus 500, an nth semiconductor chip to be placed as an nth layer is inverted by the pickup mechanism 510 and the inversion mechanism 520, and is suctioned and picked up by the collet 122. For example, if n=1, the first semiconductor chip 310a is picked up. After the nth semiconductor chip is picked up, the bonding tool 120 is raised.

In step S1203, the bonding controller 214 moves the head 110 such that the index surface 173a is on the same surface as the focal plane 110a of the first imaging unit 130 and the second imaging unit 140, and the third imaging unit 150 is positioned directly below the bonding tool 120. Furthermore, in step S1204, the bonding tool 120 is lowered such that, of the nth semiconductor chip being held, the planned contact surface to be in contact with the stacking object is on the same surface as the index surface 173a.

After such adjustment of the arrangement is completed, in step S1205, the bonding controller 214 causes the third imaging unit 150 to image the planned contact surface of the nth semiconductor chip held by the bonding tool 120. Then, in step S1206, the bottom-up image output by the third imaging unit 150 is obtained, and the three-dimensional coordinates of the reference position of the nth semiconductor chip are recognized based on the image coordinates of the chip reference mark captured in the image, etc.

In step S1207, the bonding controller 214 adjusts the position of the stage 190 such that an nth region surface is on the same surface as the index surface 173a. For example, if n=1, the stage surface 190a is moved to Z=Z₁ such that the first region surface 330a is on the same surface as the index surface 173a.

In step S1208, the bonding controller 214 raises the bonding tool 120 to a position where the nth semiconductor chip being held retracts from the field of view of the overhead imaging unit, while moving the head 110 such that the bonding tool 120 is directly above the planned placement region where the nth semiconductor chip will be placed. In the subsequent step S1209, the height of the head 110 is adjusted such that the focal plane 110a of the overhead imaging unit coincides with the nth region surface.

After such adjustment of the arrangement is completed, in step S1210, the bonding controller 214 causes the first imaging unit 130 and the second imaging unit 140 to image the vicinity of the planned placement region including reference marks such as the pad reference mark 321 and the stack reference mark 323. Then, the first overhead image output by the first imaging unit 130 and the second overhead image output by the second imaging unit 140 are obtained, and in step S1211, the three-dimensional coordinates of the target position are calculated based on the image coordinates of the reference marks captured in the images and the calibration value, etc.

After the target position is determined, the process proceeds to step S1212, where the bonding controller 214 moves the head 110 and the bonding tool 120 such that the reference position of the nth semiconductor chip matches the target position, and places the nth semiconductor chip in the planned placement region. Subsequently, the nth semiconductor chip is pressed/heated to complete the bonding. After the bonding of the nth semiconductor chip is completed, the bonding tool 120 is raised.

The bonding controller 214 proceeds to step S1213 and increments the counter n. Then, in step S1214, it is determined whether the incremented counter n exceeds a planned total stacking number n0. In the above-described embodiment, the first semiconductor chip 310a as the first layer is bonded on the lead frame 330, and the second semiconductor chip 310b as the second layer is bonded thereon, so the planned total stacking number is “2”. If the counter n does not exceed the planned total stacking number n0, the process returns to step S1202 to execute the bonding of the nth semiconductor chip corresponding to the incremented n. If the counter n exceeds the planned total stacking number n0, the process returns to the main flow.

In the embodiment described above, the calibration process and the bonding process are separated, and the calibration process is executed in the case where the state of the bonding apparatus 100 satisfies the conditions of the preset calibration timing. Thus, once the calibration process is executed, the calculated calibration value is stored in the storage part 220, and the calibration value is continuously referenced in each bonding process before the next calibration process is executed. However, the processing procedure may incorporate the calibration process into a series of bonding processes, updating the calibration value each time during the processing steps of bonding each nth semiconductor chip. Another embodiment as such will be described below. In this another embodiment below, since the configuration of the bonding apparatus itself is similar to the above-described embodiment, its description is omitted, and mainly the parts with different processing procedures are described.

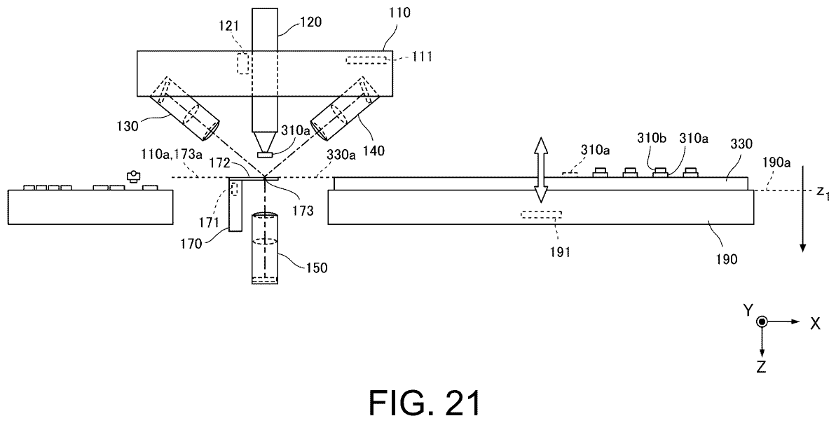

FIG. 21 is a diagram showing three imaging units imaging the calibration index 173 in another embodiment. In this embodiment, the calibration process for calculating the calibration value is executed between the pickup process of the nth semiconductor chip and the imaging process of the nth semiconductor chip by the third imaging unit 150.

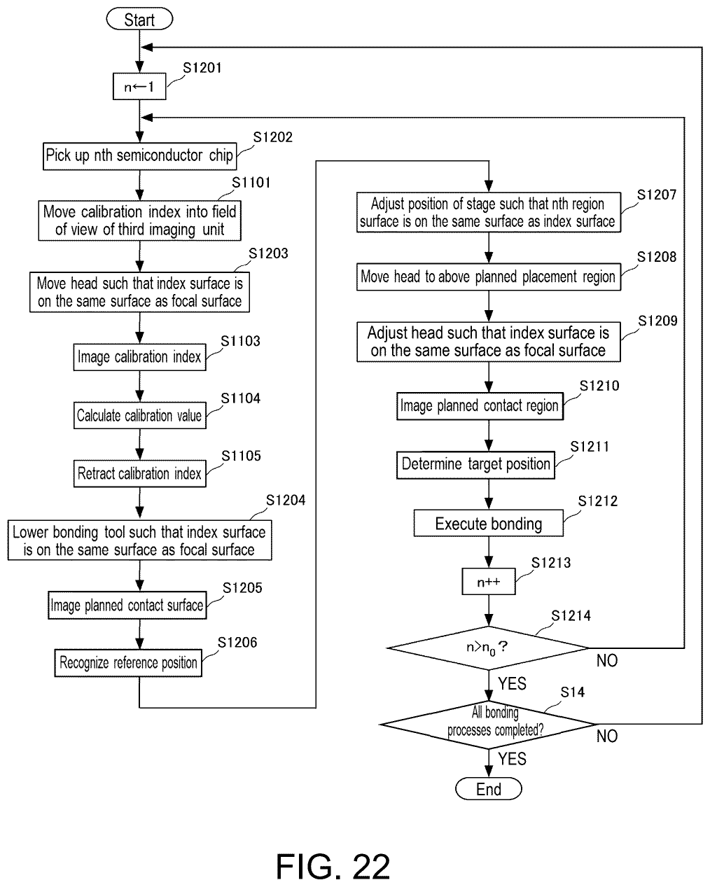

More specifically, FIG. 22 shows a state where the collet 122 holds the first semiconductor chip 310a, which is the bonding target, while they are retracted from the field of view of the overhead imaging unit. The first semiconductor chip 310a held by the collet 122 will be placed and bonded at the planned placement region on the lead frame 330, as indicated by the dotted line. Moreover, in the drawing, the position of the stage 190 is adjusted such that the first region surface 330a is at the same height as the index surface 173a. The position adjustment of the stage 190 may be executed before the bonding controller 214 starts the operation of placing the first semiconductor chip 310a in the planned placement region.

The rest is similar to the state where the three imaging units image the calibration index 173 as shown in FIG. 4. Specifically, the position of the head 110 is adjusted such that the focal plane 110a of the overhead imaging unit is at the same height as the index surface 173a. Moreover, the calibration index 173 is placed near the center of the field of view of each imaging unit.

The calibration controller 213 calculates the calibration value based on the first overhead image, the second overhead image, and the bottom-up image obtained by having each imaging unit perform imaging, as described above. After the calibration controller 213 calculates the calibration value, the bonding controller 214 continues to lower the bonding tool 120 and executes the processes following the imaging of the first semiconductor chip 310a by the third imaging unit 150, as described using FIG. 6. In this manner, the calibration value calculated in the calibration process executed in synchronization with the bonding process is used only for aligning the position of the first semiconductor chip 310a to be bonded in that bonding process.

The process is similar when bonding the second semiconductor chip 310b. The calibration process for calculating the calibration value is executed between the pickup process of the second semiconductor chip 310b and the imaging process of the second semiconductor chip 310b by the third imaging unit 150. After the calibration controller 213 calculates the calibration value based on the first overhead image, the second overhead image, and the bottom-up image obtained by having each imaging unit perform imaging, it continues to lower the bonding tool 120 and executes the processes following the imaging of the second semiconductor chip 310b by the third imaging unit 150, as described using FIG. 13. In this manner, the calibration value calculated in the calibration process executed in synchronization with the bonding process is used only for aligning the position of the second semiconductor chip 310b to be bonded in that bonding process.

In this manner, as long as the calibration controller 213 has the calibration index imaged and updates the calibration value in synchronization with the process where the bonding controller 214 has the third imaging unit 150 image the nth semiconductor chip, it is possible to shorten the time interval between the point when the calibration value is calculated and the point when the calibration value is used. Thus, it can be expected that more accurate alignment can be achieved despite temperature changes in the surrounding environment.

FIG. 22 is a flow chart illustrating the bonding procedure of semiconductor chips in this other example. For processing procedures that are identical to those described using FIG. 18 to FIG. 20, the same step numbers are assigned, and detailed descriptions of their processing contents are omitted. As described above, this example is a processing procedure that incorporates the calibration process into each bonding process, so the description will mainly focus on the flow of the process.

In step S1201, the bonding controller 214 assigns “1” to the counter n. Proceeding to step S1202, the nth semiconductor chip to be placed as the nth layer, of the semiconductor chips 310 placed on the chip supply apparatus 500, is picked up and suctioned by the collet 122. Before or after step S1202, or in parallel with step S1202, the calibration controller 213 executes step S1101 to move the index plate 172 and put the calibration index 173 into the field of view center of the third imaging unit 150.

Then, proceeding to step S1203, the calibration controller 213 moves the head 110 such that the index surface 173a is on the same surface as the focal plane 110a, and the calibration index 173 is positioned directly below the bonding tool 120.

In the subsequent step S1103, the calibration controller 213 has the first imaging unit 130, the second imaging unit 140, and the third imaging unit 150 execute imaging, and further in step S1104, calculates the calibration value. After the calibration value is calculated, the process proceeds to step S1105, where the calibration index 173 is retracted from the field of view of each imaging unit. After the calibration controller 213 retracts the calibration index 173, the subsequent steps S1204 to S1212 are similar to the processing procedure described using FIG. 20.

When proceeding from step S1212 to step S1213, the bonding controller 214 increments the counter n. Then, in step S1214, it is determined whether the incremented counter n has exceeded the planned total stacking number n0. If the counter n has not exceeded the planned total stacking number n0, the process returns to step S1202 and executes bonding of the nth semiconductor chip corresponding to the incremented n. If the counter n has exceeded the planned total stacking number n0, the process proceeds to step S14.

When the bonding controller 214 proceeds to step S14, it is determined whether all planned bonding processes have been completed. If it is determined that there are remaining semiconductor chips to be bonded, the process returns to step S1201. If it is determined determines that all bonding processes have been completed, the process ends the series of processes.

In the embodiment described above, including other examples, the bonding controller 214 adjusts the position of the stage 190 such that the region surface of the planned placement region (for example, the first region surface 330a) is at the same height as the index surface 173a exist. However, when adjusting the position of the stage 190 based on the stage surface 190a, the height of the planned placement region may not coincide with the height of the index surface 173a due to variations in the thickness of the lead frame 330 or the first semiconductor chip 310a, or the influence of adhesive. Thus, a modification example to address such an issue will be described.

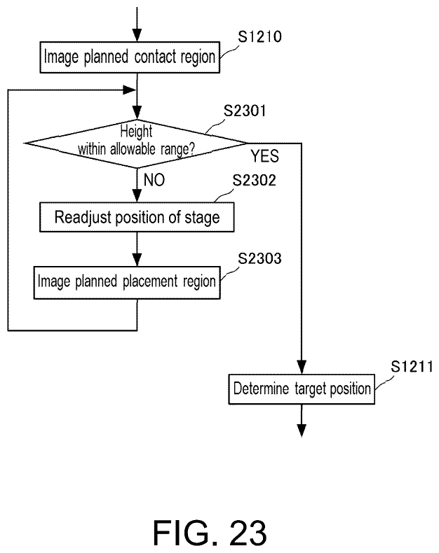

The modification example adds an additional procedure between step S1210 and step S1211 of the bonding control steps described using FIG. 20. FIG. 23 is a flow chart illustrating the additional procedure related to the modification example.

In step S1210, the bonding controller 214 has the first imaging unit 130 and the second imaging unit 140 image two overhead images of the vicinity of the planned placement region, and calculates provisional three-dimensional coordinates of the target position. The bonding controller 214 may recognize the height of the region surface of the planned placement region from the Z coordinate value of the provisional three-dimensional coordinates calculated here. Then, the process proceeds to step S2301 and it is determined whether the height of the region surface is within a preset allowable range with respect to the height of the index surface 173a measured in the calibration control step. If it is not within the range, the process proceeds to step S2302, and the stage drive motor 191 is driven through the drive controller 212 based on the recognized height of the region surface to readjust the position of the stage 190.

After the position of the stage 190 is readjusted, the bonding controller 214 has the first imaging unit 130 and the second imaging unit 140 image the vicinity of the planned placement region again in step S2303, obtain two overhead images, and calculates provisional three-dimensional coordinates of the target position in the same manner as in step S1210. After the provisional three-dimensional coordinates are calculated, the process returns to step S2301 again.

If it is determined in step S2301 that the height of the region surface is within the preset allowable range, the process proceeds to step S1211. By adding such an additional procedure between step S1210 and step S1211, the three-dimensional coordinates of the target position can be calculated more accurately.

In the embodiments described above, the overhead imaging unit was configured to include two units, the first imaging unit 130 and the second imaging unit 140, but the overhead imaging unit may be configured to include three or more imaging units, each adopting a Scheimpflug optical system. Moreover, in the embodiments described above, the three-dimensional coordinates of the target object were calculated using the parallax between the first overhead image and the second overhead image, but the method for calculating three-dimensional coordinates using the overhead imaging unit is not limited thereto. For example, there may be only one overhead imaging unit adopting a Scheimpflug optical system, and other auxiliary means may be used. For instance, a light projection part capable of pattern projection may be provided in the head 110, and the three-dimensional coordinates of the target object may be calculated by analyzing the shape of the projected pattern observed on the observation surface in the overhead image output by the overhead imaging unit. Furthermore, although the embodiment described a flip chip bonder, the present invention is not limited thereto and may be applied to die bonders, surface mounting machines that mount electronic components on substrates, and other mounting apparatuses.

### REFERENCE SIGNS LIST

100 . . . Bonding apparatus, 110 . . . Head, 110a . . . . Focal plane, 111 . . . Head drive motor, 120 . . . Bonding tool, 121 . . . Tool drive motor, 122 . . . Collet, 123 . . . Collet center, 124 . . . Heater, 130 . . . First imaging unit, 131 . . . First optical system, 131a . . . Object-side lens group, 131b . . . Image-side lens group, 132 . . . First imaging element, 133 . . . Aperture, 140 . . . Second imaging unit, 141 . . . Second optical system, 142 . . . Second imaging element, 150 . . . Third imaging unit, 150a . . . Focal plane, 151 . . . Third optical system, 152 . . . Third imaging element, 170 . . . Calibration unit, 171 . . . Index drive motor, 172 . . . Index plate, 173 . . . Calibration index, 173a . . . Index surface, 190 . . . Stage, 190a . . . Stage surface, 191 . . . Stage drive motor, 210 . . . Algorithm processor, 211 . . . Image acquisition part, 212 . . . Drive controller, 213 . . . Calibration controller, 214 . . . Bonding controller, 220 . . . Storage part, 221 . . . Calibration data, 230 . . . Input/output device, 310 . . . Semiconductor chip, 310a . . . First semiconductor chip, 310b . . . Second semiconductor chip, 311a . . . Chip reference mark, 311b . . . Chip reference mark, 320 . . . Die-pad, 321 . . . Pad reference mark, 322 . . . Unit region, 323 . . . Stack reference mark, 330 . . . Lead frame, 330a . . . First region surface, 330b . . . Second region surface, 500 . . . Chip supply apparatus, 510 . . . Pickup mechanism, 520 . . . Inversion mechanism

1. A mounting apparatus, comprising:
a mounting tool that picks up and holds a mounting body having a mounting surface, and mounts the mounting surface to a substrate placed on a stage or to a planned placement region set with respect to another mounting body already mounted on the substrate;
an overhead imaging unit having an optical system and an imaging element arranged to satisfy a Scheimpflug condition such that a plane parallel to a stage surface of the stage becomes a focal plane, for imaging the planned placement region from above from a same side as the mounting tool with respect to the stage surface;
a bottom-up imaging unit for imaging the mounting body held by the mounting tool from below from an opposite side of the overhead imaging unit with respect to the stage surface;
a calibration index arranged to be imageable by the overhead imaging unit and the bottom-up imaging unit; and
a mounting controller that adjusts a position of the mounting tool such that the mounting surface is at a same height as an index surface of the calibration index, recognizes a reference position of the mounting body based on a bottom-up image output by causing the bottom-up imaging unit to image the mounting surface, adjusts a position of the stage such that a mounted surface of the planned placement region is at the same height as the index surface, and causes mounting to the mounted surface based on the reference position.

2. The mounting apparatus according to claim 1, comprising:
a calibration controller that calculates a calibration value for calibrating a difference between a coordinate value calculated based on an overhead image output by the overhead imaging unit and a coordinate value calculated based on the bottom-up image output by the bottom-up imaging unit, based on the overhead image output by causing the overhead imaging unit to image the calibration index and the bottom-up image output by causing the bottom-up imaging unit to image the calibration index,
wherein the mounting controller adjusts a position of the overhead imaging unit such that the focal plane is at a same height as the mounted surface, recognizes a target position of the planned placement region based on the overhead image of the planned placement region imaged by the overhead imaging unit and the calibration value, and places the mounting body on the planned placement region such that the reference position matches the target position.

3. The mounting apparatus according to claim 2, wherein the calibration controller calculates and updates the calibration value each time the mounting controller completes mounting of a preset lot of the mounting bodies.

4. The mounting apparatus according to claim 2, wherein the calibration controller calculates and updates the calibration value based on an operation time of a mounting operation executed by the mounting controller.

5. The mounting apparatus according to claim 2, comprising:
a temperature detector that detects a temperature of the overhead imaging unit,
wherein the calibration controller calculates and updates the calibration value in response to the temperature detector detecting a preset temperature.

6. The mounting apparatus according to claim 2, wherein the calibration controller causes the overhead imaging unit and the bottom-up imaging unit to image the calibration index in synchronization with a process in which the mounting controller causes the bottom-up imaging unit to image the mounting surface of the mounting body, and calculates the calibration value.

7. The mounting apparatus according to claim 2, wherein the mounting controller adjusts the position of the stage after sequentially mounting a plurality of the mounting bodies on the substrate, and sequentially mounts another mounting body on each of the mounting bodies mounted on the substrate.

8. The mounting apparatus according to claim 2, wherein the mounting controller measures a height of the mounted surface when adjusting the position of the overhead imaging unit such that the focal plane is at the same height as the mounted surface, and in a case where the measured height of the mounted surface does not fall within a preset allowable range based on the index surface, readjusts the position of the stage before causing the mounting body.

9. The mounting apparatus according to claim 2,
wherein the overhead imaging unit comprises a first imaging unit and a second imaging unit adjusted such that their respective focal planes coincide, and
the mounting controller recognizes the target position by correcting a provisional target position calculated based on a first overhead image output by causing the first imaging unit to image the planned placement region and a second overhead image output by causing the second imaging unit to image the planned placement region, using the calibration value.

10. A mounting method for mounting a mounting body using a mounting apparatus, the mounting apparatus comprising:
a mounting tool that picks up and holds a mounting body having a mounting surface, and mounts the mounting surface to a substrate placed on a stage or to a planned placement region set with respect to another mounting body already mounted on the substrate; an overhead imaging unit having an optical system and an imaging element arranged to satisfy a Scheimpflug condition such that a plane parallel to a stage surface of the stage becomes a focal plane, for imaging the planned placement region from above from a same side as the mounting tool with respect to the stage surface; a bottom-up imaging unit for imaging the mounting body held by the mounting tool from below from an opposite side of the overhead imaging unit with respect to the stage surface; and a calibration index arranged to be imageable by the overhead imaging unit and the bottom-up imaging unit, and the method comprising:
a mounting control step of adjusting a position of the mounting tool such that the mounting surface is at a same height as an index surface of the calibration index, recognizing a reference position of the mounting body based on a bottom-up image output by causing the bottom-up imaging unit to image the mounting surface, adjusting a position of the stage such that a mounted surface of the planned placement region is at the same height as the index surface, and causing mounting to the mounted surface based on the reference position.

11. A computer-readable recording medium recording a mounting control program for controlling a mounting apparatus, the mounting apparatus comprising:
a mounting tool that picks up and holds a mounting body having a mounting surface, and mounts the mounting surface to a substrate placed on a stage or to a planned placement region set with respect to another mounting body already mounted on the substrate; an overhead imaging unit having an optical system and an imaging element arranged to satisfy a Scheimpflug condition such that a plane parallel to a stage surface of the stage becomes a focal plane, for imaging the planned placement region from above from a same side as the mounting tool with respect to the stage surface; a bottom-up imaging unit for imaging the mounting body held by the mounting tool from below from an opposite side of the overhead imaging unit with respect to the stage surface; and a calibration index arranged to be imageable by the overhead imaging unit and the bottom-up imaging unit, the program computer-readable recording medium causing a computer to execute:
a mounting control step of adjusting a position of the mounting tool such that the mounting surface is at a same height as an index surface of the calibration index, recognizing a reference position of the mounting body based on a bottom-up image output by causing the bottom-up imaging unit to image the mounting surface, adjusting a position of the stage such that a mounted surface of the planned placement region is at the same height as the index surface, and causing mounting to the mounted surface based on the reference position.

12. The mounting apparatus according to claim 3,
wherein the overhead imaging unit comprises a first imaging unit and a second imaging unit adjusted such that their respective focal planes coincide, and
the mounting controller recognizes the target position by correcting a provisional target position calculated based on a first overhead image output by causing the first imaging unit to image the planned placement region and a second overhead image output by causing the second imaging unit to image the planned placement region, using the calibration value.

13. The mounting apparatus according to claim 4,
wherein the overhead imaging unit comprises a first imaging unit and a second imaging unit adjusted such that their respective focal planes coincide, and
the mounting controller recognizes the target position by correcting a provisional target position calculated based on a first overhead image output by causing the first imaging unit to image the planned placement region and a second overhead image output by causing the second imaging unit to image the planned placement region, using the calibration value.

14. The mounting apparatus according to claim 5,
wherein the overhead imaging unit comprises a first imaging unit and a second imaging unit adjusted such that their respective focal planes coincide, and
the mounting controller recognizes the target position by correcting a provisional target position calculated based on a first overhead image output by causing the first imaging unit to image the planned placement region and a second overhead image output by causing the second imaging unit to image the planned placement region, using the calibration value.

15. The mounting apparatus according to claim 6,
wherein the overhead imaging unit comprises a first imaging unit and a second imaging unit adjusted such that their respective focal planes coincide, and
the mounting controller recognizes the target position by correcting a provisional target position calculated based on a first overhead image output by causing the first imaging unit to image the planned placement region and a second overhead image output by causing the second imaging unit to image the planned placement region, using the calibration value.

16. The mounting apparatus according to claim 7,
wherein the overhead imaging unit comprises a first imaging unit and a second imaging unit adjusted such that their respective focal planes coincide, and
the mounting controller recognizes the target position by correcting a provisional target position calculated based on a first overhead image output by causing the first imaging unit to image the planned placement region and a second overhead image output by causing the second imaging unit to image the planned placement region, using the calibration value.

17. The mounting apparatus according to claim 8,
wherein the overhead imaging unit comprises a first imaging unit and a second imaging unit adjusted such that their respective focal planes coincide, and
the mounting controller recognizes the target position by correcting a provisional target position calculated based on a first overhead image output by causing the first imaging unit to image the planned placement region and a second overhead image output by causing the second imaging unit to image the planned placement region, using the calibration value.
